(19) United States
(12) Patent Application Publication
(10) Pub. No.: US 2016/0370813 A1
(43) Pub. Date: Dec. 22, 2016

(54) Thermostat Assembly and Method of Manufacturing

(71) Applicant: Phillips & Temro Industries Inc., Eden Prairie, MN (US)

(72) Inventor: Mark H. Hoglund, Eagan, MN (US)

(21) Appl. No.: 14/744,192

(22) Filed: Jun. 19, 2015

(51) Int. Cl. G05D 23/19; H05K 5/02

(52) U.S. Cl. CPC G05D 23/19; H05K 5/0247

(57) ABSTRACT

A thermostat assembly may include a thermostat, first and second wires, and first and second housings. The first wire may be electrically connected to the thermostat at a first connection interface. The second wire may be electrically connected to the thermostat at a second connection interface. The first housing may encapsulate the thermostat and the first and second connection interfaces to form a moisture barrier around the thermostat and the first and second connection interfaces. The second housing may encapsulate the first housing, the thermostat, and the first and second connection interfaces. Compression seals and/or one or more applications of a bonding agent may provide further redundancies and moisture-contamination barrier effectiveness.

### FIELD

The present disclosure relates to a thermostat assembly and a method of manufacturing the thermostat assembly.

### BACKGROUND

This section provides background information related to the present disclosure and is not necessarily prior art.

Thermostats for controlling operation of vehicle systems are routinely exposed to a variety of harsh operating conditions. For example, typical thermostat assemblies can be exposed to extreme hot and cold temperatures, moisture, chemicals, vibration and mechanical shock, for example. Traditional plug-style thermostat assemblies can be difficult to seal and are prone to failure. The present disclosure provides a thermostat assembly that has improved durability of functionality.

### SUMMARY

This section provides a general summary of the disclosure, and is not a comprehensive disclosure of its full scope or all of its features.

In one form, the present disclosure provides a thermostat assembly that may include a thermostat, first and second wires, and first and second housings. The first wire may be electrically connected to the thermostat at a first connection interface. The second wire may be electrically connected to the thermostat at a second connection interface. The first housing may encapsulate the thermostat and the first and second connection interfaces to form a moisture barrier around the thermostat and the first and second connection interfaces. The second housing may encapsulate the first housing, the thermostat, and the first and second connection interfaces.

In some configurations, the thermostat assembly may include a thermostat cap covering an end of the thermostat.

In some configurations, the thermostat cap is encapsulated in the first housing.

In some configurations, the first and second connection interfaces are coated with a bonding agent.

In some configurations, an exterior surface of the first housing is at least partially coated with the bonding agent.

In some configurations, the first and second wires extend from the thermostat in opposite directions and extend outward from the second housing in opposite directions.

In some configurations, the first and second housings encapsulate insulated portions of the first and second wires.

In some configurations, a slot is formed in an exterior of the second housing.

In some configurations, a barb extends into the slot.

In some configurations, the second housing includes a plurality of apertures extending therethrough in a direction perpendicular to longitudinal axes of the first and second wires.

In some configurations, the first and second housings are formed from thermoplastic rubber.

In some configurations, the first housing includes a plurality of apertures extending at least partially therethrough. The plurality of apertures may be filled by the second housing.

In another form, the present disclosure provides a method of manufacturing a thermostat assembly. The method may include connecting a first wire for electrical communication with a thermostat at a first electrical connection interface; connecting a second wire for electrical communication with the thermostat at a second electrical connection interface; encapsulating the thermostat and the first and second electrical connection interfaces in a first molding; and encapsulating the thermostat, the first and second electrical connection interfaces, and the first molding in a second molding.

In some configurations, the method includes mounting a thermostat cap onto the thermostat before encapsulating the thermostat in the first molding.

In some configurations, the method includes applying a bonding agent to the first and second electrical connection interfaces before encapsulating the first and second electrical connection interfaces in the first molding.

In some configurations, the method includes applying the bonding agent to the first molding before encapsulating the first molding in the second molding.

In some configurations, the step of encapsulating the thermostat and the first and second electrical connection interfaces in the first molding includes overmolding the thermostat and the first and second electrical connection interfaces.

In some configurations, the step of encapsulating the first molding in the second molding includes overmolding the first molding after the first molding has solidified.

In some configurations, a plurality of apertures are formed in the first molding during a molding process forming the first molding. The plurality of apertures are filled by the second molding when the second molding is molded over the first molding.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic representation of an electrical system including a sealed thermostat assembly according to the principles of the present disclosure;

FIG. 2 is a perspective view of the thermostat assembly;

FIG. 3 is a top view of the thermostat assembly;

FIG. 4 is an end view of the thermostat assembly;

FIG. 5 is a side view of the thermostat assembly;

FIG. 6 is a top view of an inner molding of the thermostat assembly;

FIG. 7 is a side view of the inner molding of the thermostat assembly;

FIG. 8 is a side view of a thermostat of the thermostat assembly;

FIG. 9 is a cross-sectional view of a thermostat cap of the thermostat assembly;

FIG. 10 is a bottom view of another thermostat assembly having an outer molding with a slot formed therein;

FIG. 11 is a side view of the thermostat assembly of FIG. 10; and

FIG. 12 is a flowchart illustrating a method of manufacturing the thermostat assembly of FIG. 2 or FIG. 10.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

With reference to FIG. 1, a power cord assembly 8 is provided that may include a sealed thermostat assembly 10, a first plug or terminal 11 and a second plug or terminal 13. The thermostat assembly 10 may be electrically connected to the first plug 11 via wires 16, 20, 22 and electrically connected to the second plug 13 via wires 18, 20, 22. The first plug 11 may be electrically coupled to an electrical power source 15 (e.g., a battery or an alternating current receptacle), and the second plug 13 may be electrically coupled to an electrical device 17 (e.g., an air-intake heater, an engine block heater, a cabin heater or a coolant system for a vehicle, or any other temperature-dependent system). The thermostat assembly 10 may be used to sense a temperature within a space (e.g., an engine compartment or other space within the body of a vehicle) and move a switch between closed and open positions (i.e., to allow and prevent a flow of electrical current through the thermostat assembly 10) when the temperature within the space reaches a selected setpoint temperature. In this manner, the thermostat assembly 10 may selectively allow and prevent electrical communication between the power source 15 and the electrical device 17.

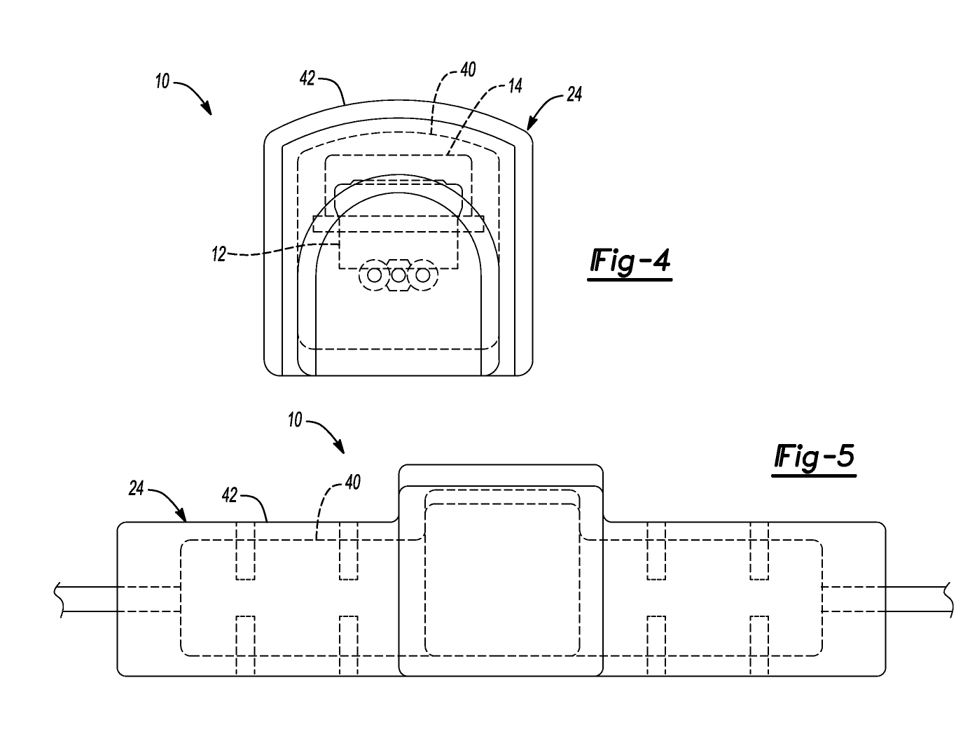

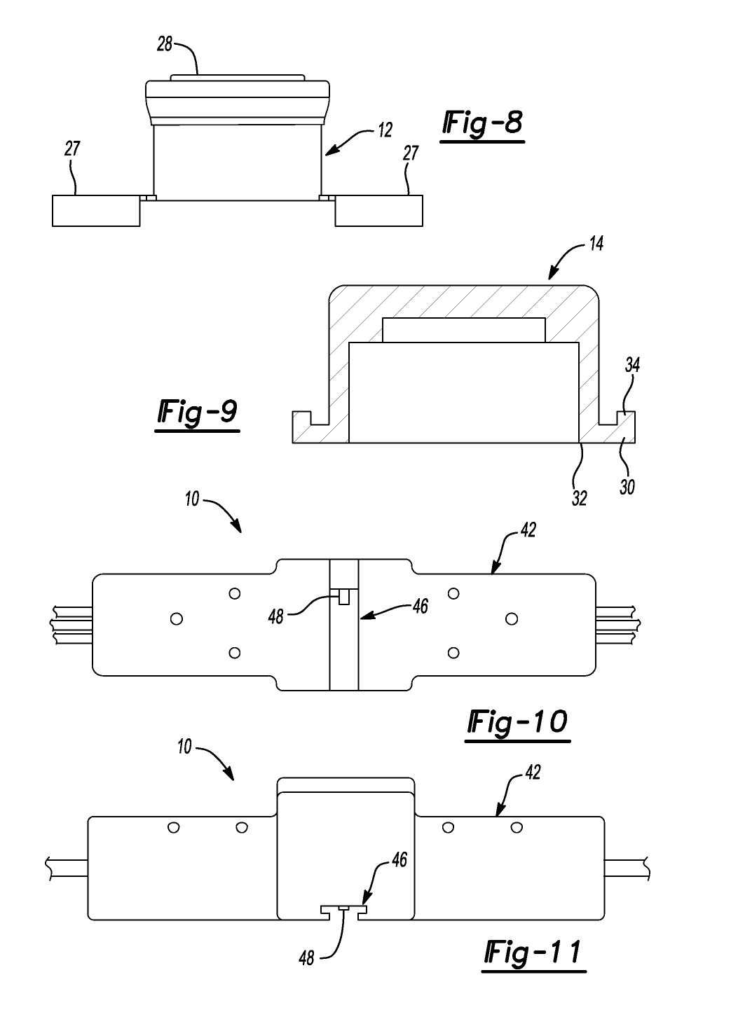

Referring now to FIGS. 2-9, the thermostat assembly 10 may include a thermostat 12 (FIGS. 4 and 8), a thermostat cap 14 (FIGS. 4 and 9), a first wire 16, a second wire 18, a third wire 20, a fourth wire 22 and a housing assembly 24. As will be described in more detail below, the housing assembly 24 may encapsulate the thermostat 12, cap 14 and portions of wires 16, 18, 20, 22 and provides multiple moisture and contamination barriers to protect the thermostat 12 and electrical connections with the thermostat 12 from moisture, de-icing chemicals, salt, dirt, oil and other contaminants.

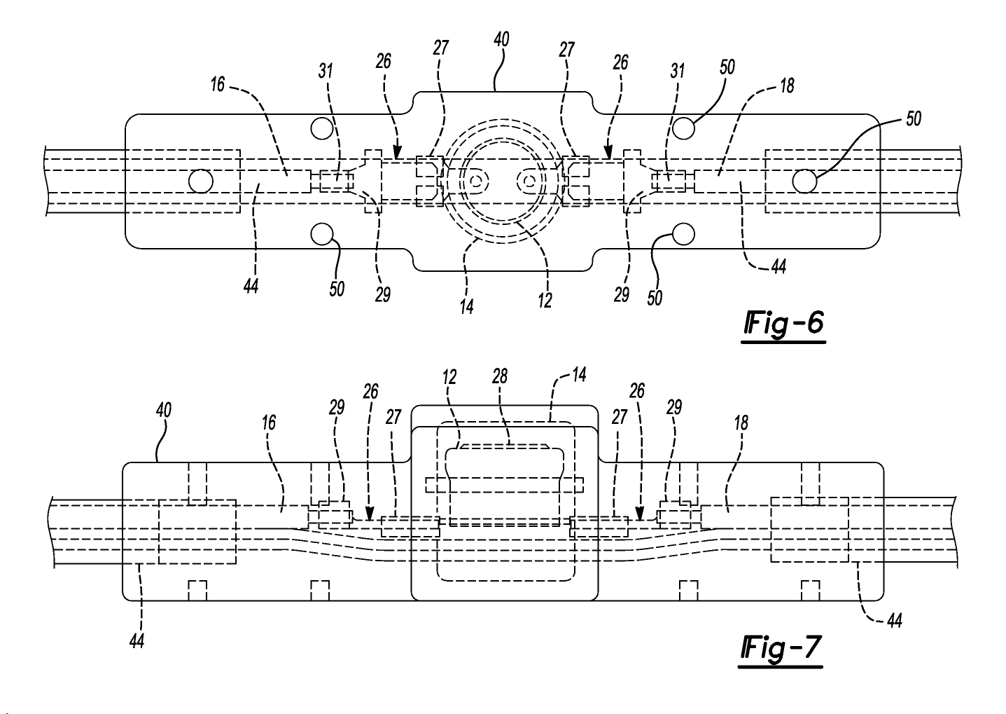

As shown in FIGS. 6 and 7, the first and second wires 16, 18 may be connected to the thermostat 12 via electrical connection interfaces 26 to provide electrical communication among the first and second wires 16, 18 and the thermostat 12. The connection interfaces 26 could be quick-connect interfaces including female terminals 27 and male terminals 29, for example. In some configurations, the female terminals 27 may be attached to the thermostat 12 and may receive the male terminals 29, which may be attached to uninsulated ends 31 of the wires 16, 18. As will be subsequently described, one or more coatings of a bonding agent may be applied to and around the connection interfaces 26 and/or the thermostat 12 to provide moisture and contaminant barriers around the connection interfaces 26 and/or the thermostat 12. As shown in the figures, the first and second wires 16, 18 may extend outward from the thermostat 12 in opposite directions. In some configurations, the third and fourth wires 20, 22 may extend around the thermostat 12 (as shown in FIG. 7). As shown in the figures, the assembly 10 is an inline configuration (i.e., the thermostat 12 is disposed within the housing assembly 24 with wires 16, 18, 20, 22 extending out of opposite ends of the housing assembly 24).

As shown in FIG. 8, the thermostat 12 may include a temperature-sensing end portion 28. For example, the thermostat 12 could be a Honeywell Elmwood Series 3004 sensor. It will be appreciated that the assembly 10 could accommodate a variety of types of thermostats, such as normally open, normally closed, ceramic snap disk, heavy duty phenolic snap disk, reed, adjustable setting, or manual rest type thermostats, for example.

As shown in FIGS. 4 and 7, the cap 14 may be mounted on the thermostat 12 such that the temperature-sensing end portion 28 is disposed within and covered by the cap 14. As shown in FIG. 9, the cap 14 can be a generally cup-shaped member having an annular rim 30 at an open end 32 of the cap 14. The rim 30 may extend radially outward and may surround the open end 32. In some configurations, the rim 30 may include a lip 34.

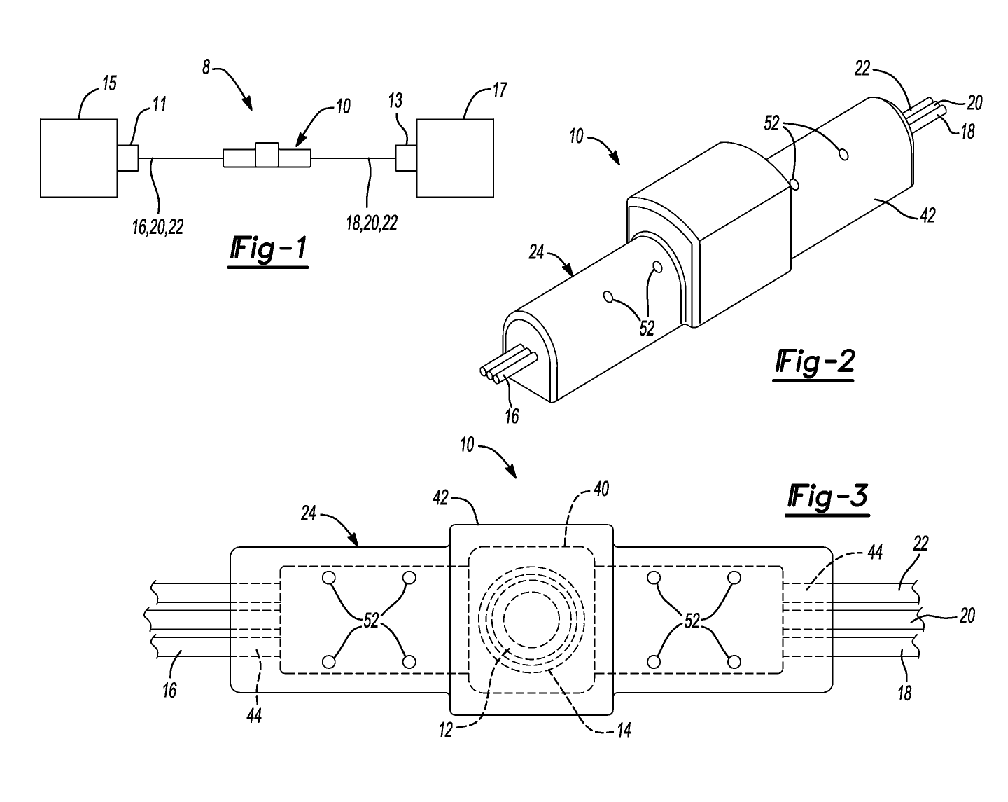

As shown in FIGS. 3-5, the housing assembly 24 may include an inner housing or molding 40 and an outer housing or molding 42. The outer molding 42 is larger than the inner molding 40 and surrounds the inner molding 40. The inner and outer moldings 40, 42 can be formed from a thermoplastic rubber (TPR), for example, or any other suitable material. As shown in FIGS. 6 and 7, the inner molding 40 surrounds and encapsulates the thermostat 12, the cap 14, the connection interfaces 26 and at least a portion of the insulated portions 44 of wires 16, 18, 20, 22. The inner molding 40 may be molded over the thermostat 12, the cap 14, the connection interfaces 26 and the portions of the insulated portions 44 of the wires 16, 18, 20, 22, thereby sealingly encapsulating the thermostat 12, the cap 14 and the connection interfaces 26. In this manner, the inner molding 40 provides another moisture and contaminant barrier for the thermostat 12, the cap 14 and the connection interfaces 26.

As shown in FIGS. 3 and 5, the outer molding 42 may be molded over and around the entire inner molding 40 to completely encapsulate the inner molding 40 thermostat 12, the cap 14, the connection interfaces 26 and an additional length of the insulated portions 44 of the wires 16, 18, 20, 22. In this manner, the outer molding 42 provides an additional moisture and contaminant barrier for the thermostat 12, the cap 14 and the connection interfaces 26. Therefore, the assembly 10 includes multiple redundant moisture and contaminant barriers, i.e., the inner and outer moldings 40, 42 and the one or more coatings of the bonding agent.

The inner and outer moldings 40, 42 can accommodate “Y” and “W” wiring configurations for either series or parallel circuitry. The TPR material used to form the inner and outer moldings 40, 42 as well as the shapes of the inner and outer moldings 40, 42 shown in the figures can assist with thermal regulation of the thermostat 12. Furthermore, the TPR material is very durable and withstands the temperature extremes, moisture, contamination, vibration and road shock that are often encountered in a vehicle under-hood environment. The TPR material is resistant to combustion or flame propagation.

In the configuration shown in FIGS. 10 and 11, the outer molding 42 may include one or more slots 46 formed therein. The slot 46 may receive a fastener (not shown) or other structure for mounting the assembly 10 within a vehicle, for example. In the particular configuration shown in FIGS. 10 and 11, the slot 46 may be generally T-shaped. A barbed protrusion 48 may extend into the slot 46 and may snap into engagement with the fastener or other structure.

The assembly 10 can accommodate a variety of under-hood installation methods including attachment to vehicle surfaces via one or more clips, zip ties, clamps, etc. Additional or alternative mounting features can be incorporated into the outer molding 42.

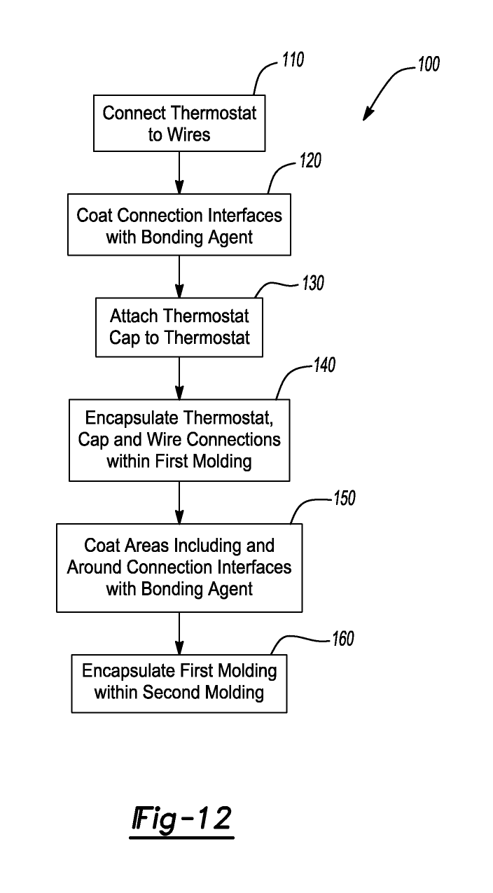

Referring now to FIG. 12, a method 100 is provided for manufacturing the assembly 10. At step 110, the wires 16, 18 may be electrically connected to the thermostat 12 by connecting the connection interfaces 26. Then, at step 120, the connection interfaces 26 (and optionally, portions of the wires 16, 18 and/or thermostat adjacent the connection interfaces 26) may be coated with a bonding agent. The bonding agent forms a preliminary moisture and contaminant barrier around the connection interfaces 26.

At step 130, the cap 14 may be attached to the thermostat 12 such that the temperature-sensing end portion 28 is received within the cap 14, as shown in FIGS. 4 and 7. In some configurations, the cap 14 could be press fit or snap fit onto the thermostat 12 and/or otherwise secured thereto. The cap 14 protects the temperature-sensing end portion 28 from the high pressure associated with the process of molding the inner molding 40. That is, the cap 14 shields the temperature-sensing end portion 28 from the hot, liquid TPR from which the inner molding 40 is formed. It will be appreciated that step 130 could be performed before step 120 or before step 110.

After steps 110, 120 and 130, the thermostat 12, connection interfaces 26 and portions of the insulated portions 44 of the wires 16, 18, 20, 22 can be encapsulated by the inner molding 40 at step 140. Step 140 may include holding the thermostat 12, connection interfaces 26 and portions of the insulated portions 44 of the wires 16, 18, 20, 22 within a first die while melted or liquefied TPR (or other material) is introduced into the first die and is allowed to solidify therein to form the inner molding 40. For example, the inner molding 40 may be overmolded in an injection molding process, a blow molding process or any other suitable molding process. The thermostat 12, connection interfaces 26 and wires 16, 18, 20, 22 may be held in place within the first die by a plurality of locating pins. The inner molding 40 may be formed while the locating pins are holding the thermostat 12, connection interfaces 26 and wires 16, 18, 20, 22. Thereafter, the locating pins can be removed. Removing the locating pins may form apertures 50 (FIG. 6) in the inner molding 40. It will be appreciated that the quantities, locations, diameters, forms and/or lengths of the apertures 50 could vary from the configuration shown in the figures. The apertures 50 may be filled and sealed with TPR when the outer molding 42 is formed.

Next, at step 150, some or all of the inner molding 40 can be coated with the bonding agent to provide yet another moisture and contaminant barrier around the thermostat 12 and the connection interfaces 26. Then, at step 160, the outer molding 42 may be overmolded around the inner molding 40 in a second die in an injection molding process, a blow molding process or any other suitable molding process. The inner molding 40 may be held in place within the second die by a plurality of locating pins. The outer molding 42 may be formed while the locating pins are holding the inner molding 40. Thereafter, the locating pins can be removed. Removing the locating pins may form apertures 52 (FIGS. 2 and 3) in the outer molding 42. It will be appreciated that the quantities, locations, diameters, forms and/or lengths of the apertures 52 could vary from the configuration shown in the figures. In some configurations, a compression seal may be inserted into the outer molding 42 at the locations through which the wires 16, 18, 20, 22 exit the outer molding 42 to prevent moisture and/or contaminant ingress.

It will be appreciated that the wires 16, 18, 20, 22 could be any suitable type of wires or cables, such as flat-jacketed cables with parallel inner conductors (e.g., HPN cable family and CPE jacket material) or round-jacketed cables with grouped inner conductors (e.g., SJ cable family and EPDM jacket material), for example. The housing 24 and method of manufacturing described above thoroughly seals and protects the thermostat 12 and connection interfaces 26 regardless of the shapes, materials and configurations of the wires 16, 18, 20, 22 and connectors or terminals 27, 29. Furthermore, the power cord assembly 8 described herein has been approved for use (with an approved mating engine heater) by the Canadian Standards Association to both Canadian and United States standards. Furthermore, the power cord assembly 8 has undergone testing and demonstrated achieving performance objectives in excess of the prior art.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A thermostat assembly comprising:
a thermostat;
a first wire electrically connected to the thermostat at a first connection interface;
a second wire electrically connected to the thermostat at a second connection interface;
a first housing encapsulating the thermostat and the first and second connection interfaces to form a moisture barrier around the thermostat and the first and second connection interfaces; and
a second housing encapsulating the first housing, the thermostat, and the first and second connection interfaces.

2. The thermostat assembly of claim 1, further comprising a thermostat cap covering an end of the thermostat.

3. The thermostat assembly of claim 2, wherein the thermostat cap is encapsulated in the first housing.

4. The thermostat assembly of claim 1, wherein the first and second connection interfaces are coated with a bonding agent.

5. The thermostat assembly of claim 4, wherein an exterior surface of the first housing is at least partially coated with the bonding agent.

6. The thermostat assembly of claim 1, wherein the first and second wires extend from the thermostat in opposite directions and extend outward from the second housing in opposite directions.

7. The thermostat assembly of claim 1, wherein the first and second housings encapsulate insulated portions of the first and second wires.

8. The thermostat assembly of claim 1, wherein a slot is formed in an exterior of the second housing.

9. The thermostat assembly of claim 8, wherein a barb extends into the slot.

10. The thermostat assembly of claim 1, wherein the second housing includes a plurality of apertures extending at least partially therethrough in a direction perpendicular to longitudinal axes of the first and second wires.

11. The thermostat assembly of claim 1, wherein the first and second housings are formed from thermoplastic rubber.

12. The thermostat assembly of claim 1, wherein the first housing includes a plurality of apertures extending at least partially therethrough, the plurality of apertures being filled by the second housing.

13. A thermostat assembly comprising:
a thermostat;
a thermostat cap covering an end of the thermostat;
a first wire electrically connected to the thermostat at a first connection interface, the first connection interface coated with a bonding agent;
a second wire electrically connected to the thermostat at a second connection interface, the second connection interface coated with the bonding agent;
a first housing encapsulating the thermostat, the thermostat cap, and the first and second connection interfaces to form a moisture barrier around the thermostat and the first and second connection interfaces, wherein an exterior surface of the first housing is at least partially coated with the bonding agent; and
a second housing encapsulating the first housing, the thermostat, and the first and second connection interfaces,
wherein the first and second wires extend from the thermostat in opposite directions, and wherein the first and second housings encapsulate insulated portions of the first and second wires.

14. The thermostat assembly of claim 13, wherein the second housing includes a plurality of apertures extending therethrough in a direction perpendicular to longitudinal axes of the first and second wires.

15. The thermostat assembly of claim 14, wherein a slot is formed in an exterior of the second housing.

16. The thermostat assembly of claim 15, wherein a barb extends into the slot.

17. The thermostat assembly of claim 16, wherein the first housing includes a plurality of apertures extending at least partially therethrough, the plurality of apertures being filled by the second housing.

18. The thermostat assembly of claim 13, wherein the first and second housings are formed from thermoplastic rubber.

19. A method of manufacturing a thermostat assembly comprising:
connecting a first wire for electrical communication with a thermostat at a first electrical connection interface;
connecting a second wire for electrical communication with the thermostat at a second electrical connection interface;
encapsulating the thermostat and the first and second electrical connection interfaces in a first molding; and
encapsulating the thermostat, the first and second electrical connection interfaces, and the first molding in a second molding.

20. The method of claim 19, further comprising mounting a thermostat cap onto the thermostat before encapsulating the thermostat in the first molding.

21. The method of claim 20, further comprising applying a bonding agent to the first and second electrical connection interfaces before encapsulating the first and second electrical connection interfaces in the first molding.

22. The method of claim 21, further comprising applying the bonding agent to the first molding before encapsulating the first molding in the second molding.

23. The method of claim 22, wherein the step of encapsulating the thermostat and the first and second electrical connection interfaces in the first molding includes overmolding the thermostat and the first and second electrical connection interfaces.

24. The method of claim 23, wherein the step of encapsulating the first molding in the second molding includes overmolding the first molding after the first molding has solidified.

25. The method of claim 24, wherein a plurality of apertures are formed in the first molding during a molding process forming the first molding, the plurality of apertures being filled by the second molding when the second molding is molded over the first molding.
